(19) United States
(12) Patent Application Publication
(10) Pub. No.: US 2026/0085424 A1
(43) Pub. Date: Mar. 26, 2026

(54) SEALING SYSTEM FOR LOW TEMPERATURE REACTION CHAMBERS

(71) Applicant: ASM IP Holding B.V., Almere (NL)

(72) Inventor: Kenneth Honniball, Kessel-Lo (LEUVEN) (BE)

(21) Appl. No.: 19/334,889

(22) Filed: Sep. 21, 2025

Related U.S. Application Data
(60) Provisional application No. 63/697,623, filed on Sep. 23, 2024.

(51) Int. Cl. C23C 16/458; C23C 16/44

(52) U.S. Cl. CPC C23C 16/4585; C23C 16/4409

(57) ABSTRACT

A reaction chamber may comprise a susceptor configured to support a substrate disposed in the reaction chamber volume, an upper chamber space above the susceptor, a lower chamber space below the susceptor, and/or a sealing system. The sealing system may cause the upper chamber space and the lower chamber space to be at least partially fluidly separated. The sealing system may comprise a spacer plate surrounding and/or a sealing member attached to the susceptor. The sealing system may be configured to form at least a partial vacuum seal between the spacer plate and the sealing member and cause at least partial fluid separation between the upper chamber space and the lower chamber space.

### CROSS-REFERENCE TO RELATED APPLICATION(S)

This application claims the benefit of U.S. Provisional Application 63/697,623 filed on Sep. 23, 2024, the entire contents of which are incorporated herein by reference.

### FIELD OF INVENTION

The present disclosure relates generally to a semiconductor processing or reactor system. Particularly, the present disclosure relates to a reactor system and to components comprised therein, which allow sealing between an upper and lower volume within a reaction chamber.

### BACKGROUND OF THE DISCLOSURE

Reaction chambers may be used for a variety of processes during the formation of electronic devices on semiconductor substrates. For example, reaction chambers can be used for depositing various material layers onto the semiconductor substrates, etching materials, and/or cleaning surfaces.

Reaction chambers may comprise two spaces or volumes that are separated, for example, by a susceptor. The two spaces may comprise an upper chamber space above the susceptor and/or a lower chamber space below the susceptor. The lower chamber space may be disposed vertically below the upper chamber space, while the upper chamber space may be disposed vertically above the susceptor.

Processing operations of one or more substrates may occur in the upper reaction space, and during the operations, contaminants may undesirably transfer from one chamber space to another. For example, contaminants may undesirably transfer from the upper chamber space to the lower chamber space. Furthermore, if the lower chamber space is sealed off from the upper chamber space, the overall volume of space where processing operations of substrates occur may be reduced, and therefore, less quantity of materials may be used during the formation of electronic devices on the substrates. Therefore, systems and methods for providing a seal between the two spaces within the reaction chamber (e.g., to at least partially fluidly separate the two chambers) may be desirable.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

The reactor system disclosed herein may facilitate at least partial sealing between two spaces, chambers, or volumes within a reaction chamber of a reactor system. In various embodiments, the reactor system may comprise a reaction chamber where one of the two spaces within the reaction chamber may be in fluid communication with the other space. A reaction chamber may comprise: a susceptor configured to support a substrate disposed in the reaction chamber and translate upwardly and downwardly within the reaction chamber; an upper chamber space within the reaction chamber and above the susceptor; a lower chamber space within the reaction chamber and below the susceptor; and a sealing system. The sealing system may comprise a sealing member attached to the susceptor; and a spacer plate surrounding the susceptor. The sealing system may be configured to form at least a partial vacuum seal between the spacer plate and the sealing member and cause at least partial fluid separation between the upper chamber space and the lower chamber space.

In some embodiments, the sealing system may be configured to form the partial vacuum seal between an upward facing surface of the sealing member and a downward facing surface of the spacer plate.

In some embodiments, the sealing member may comprise an elastic material and may be configured to expand when the partial vacuum seal is formed between the spacer plate and the sealing member.

In some embodiments, the spacer plate may comprise a first raised portion, a second raised portion, and a depressed portion between the first raised portion and the second raised portion. The sealing system may be configured to form the partial vacuum seal between the spacer plate and the sealing member by forming a vacuum process in a space formed by sidewalls of the first and the second raised portions, the depressed portion, and an upward facing surface of the sealing member. In some embodiments, one of the first raised portion or the second raised portion may comprise a width of 5 to 30 millimeters. In some embodiments, the depressed portion of the spacer place may comprise a width of 5 to 30 millimeters.

In some embodiments, the sealing system may further comprise one or more bits disposed on a first surface of the depressed portion. The bits may be configured to prevent the upward facing surface of the sealing member from contacting the first surface of the depressed portion.

In some embodiments, the reaction chamber may be configured to process the substrate at a temperature of less than 200° C.

In some embodiments, the sealing system may further comprise a vacuum source coupled to the spacer plate. The sealing system may be configured to form the partial vacuum seal between the spacer plate and the sealing member by causing the susceptor to translate upwardly within the reaction chamber, causing an upward facing surface of the sealing member to contact a downward facing surface of the spacer plate, and activating the vacuum source to form the partial vacuum seal between the spacer plate and the sealing member.

In some embodiments, the sealing system may be further configured to form the partial vacuum seal between the spacer plate and the sealing member by increasing a pressure in the lower chamber space.

In some embodiments, the sealing system may be further configured to release the partial vacuum seal between the spacer plate and the sealing member by deactivating the vacuum source and causing the susceptor to translate downward within the reaction chamber.

In some embodiments, the spacer plate may comprise a metal or metal alloy (e.g., aluminum). In some embodiments, the sealing member may comprise an elastic material (e.g., Kalrez® brand products or Viton™ brand products).

In various embodiments, a method may comprise translating a susceptor in a reaction chamber upwardly from a first position to a second position; contacting, based on the translating, an upward facing surface of a sealing member with a downward facing surface of a spacer plate in the reaction chamber where the sealing member is coupled to the susceptor and the spacer plate surrounds the susceptor; activating a vacuum source, coupled to the spacer plate, to form at least a partial vacuum seal between the downward facing surface of the spacer plate and the upward facing surface of the sealing member and to cause at least partial fluid separation between an upper chamber space of the reaction chamber and a lower chamber space, where the upper chamber space is above the susceptor and the lower chamber space is below the susceptor; and maintaining, during the processing of a substrate within the upper chamber space, the partial vacuum seal between the spacer plate and the sealing member.

In some embodiments, the method may further comprise increasing pressure in the lower chamber space.

In some embodiments, the method may further comprise, after the processing of the substrate, deactivating the vacuum source to release the partial vacuum seal and translating the susceptor downwardly from the second position to a third position.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the embodiments disclosed herein may be carried out in a manner that achieves or optimizes one advantage or group of advantages as taught or suggested herein without necessarily achieving other objects or advantages as may be taught or suggested herein.

All of these embodiments are intended to be within the scope of the disclosure. These and other embodiments will become readily apparent to those skilled in the art from the following detailed description of certain embodiments having reference to the attached figures, the disclosure not being limited to any particular embodiment(s) discussed.

### BRIEF DESCRIPTION OF THE DRAWING FIGURES

While the specification concludes with claims particularly pointing out and distinctly claiming what are regarded as embodiments of the disclosure, the advantages of embodiments of the disclosure may be more readily ascertained from the description of certain examples of the embodiments of the disclosure when read in conjunction with the accompanying drawings. Elements with the like element numbering throughout the figures are intended to be the same.

FIG. 1 is a schematic diagram of an exemplary reactor system in accordance with various embodiments.

FIG. 2A is a schematic diagram of an exemplary reaction chamber with a susceptor disposed in a lower position, in accordance with various embodiments.

FIG. 2B is a schematic diagram of an exemplary reaction chamber with a susceptor disposed in a raised position, in accordance with various embodiments.

FIGS. 3A and 3B illustrate an exemplary spacer plate for providing a seal within a reaction chamber in accordance with various embodiments.

FIG. 4 illustrates a method for maintaining a seal within a reaction chamber in accordance with various embodiments.

FIGS. 5, 6, 7, 8, and 9 illustrate schematic diagrams of a portion of a reaction chamber in accordance with various embodiments.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, apparatus, structure, or device, but are merely representations that are used to describe embodiments of the disclosure.

As used herein, the term “substrate” may refer to any underlying material or materials, including any underlying material or materials that may be modified, or upon which, a device, a circuit, or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle, the precursor is chemisorbed to a deposition surface (e.g., a substrate surface or a previously deposited underlying surface such as material from a previous ALD cycle), forming a monolayer or sub-monolayer that does not readily react with additional precursor (e.g., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) may refer to any process wherein a substrate is exposed to one or more volatile precursors, which react and/or decompose on a substrate surface to produce a desired deposition.

As used herein, the terms “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise a material or a layer with pinholes, but still be at least partially continuous.

As used herein, the term “contaminant” may refer to any unwanted material disposed within the reaction chamber that may affect the purity of a substrate disposed in the reaction chamber. The term “contaminant” may refer to, but is not limited to, unwanted deposits, metal and nonmetal particles, impurities, and waste products, disposed within the reactor system or reaction chamber, or any portion thereof.

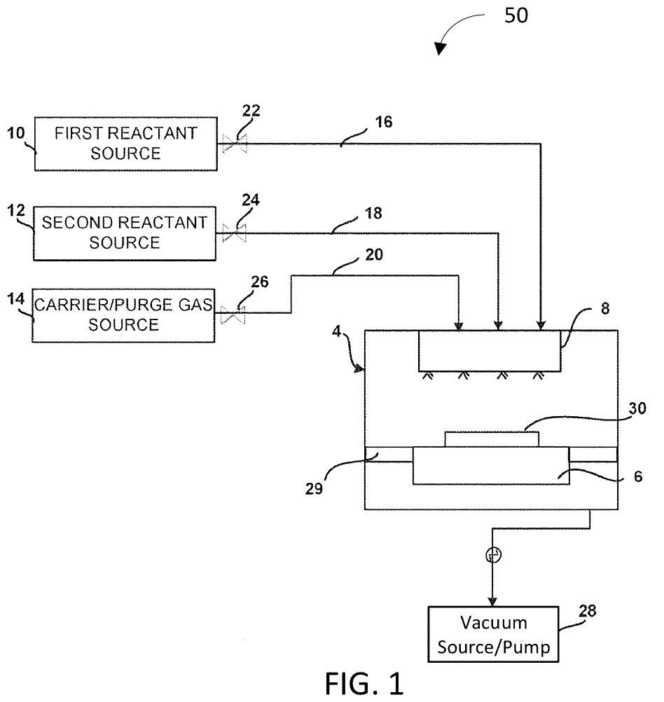

Reactor systems used for ALD, CVD, and/or the like, may be used for a variety of applications, including depositing and etching materials on a substrate surface. In various embodiments, with reference to FIG. 1, a reactor system 50 may comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16, 18, and 20, and/or valves or controllers 22, 24, and 26. The reactor system 50 may also comprise a vacuum source/pump 28 fluidly coupled to the reaction chamber 4. One or more sealing systems 29 may separate (e.g., at least partially separate fluidly) portions of a volume within reaction chamber 4.

While FIG. 1 illustrates the sealing systems 29 being implemented in a vertical furnace (e.g., the reactor system 50) accommodating a single substrate (e.g., substrate 30) oriented substantially horizontally. The sealing systems described herein may also be implemented in vertical batch furnaces that accommodate multiple substrates, diffusion ovens, horizontal furnaces where wafers are oriented vertically, and/or other furnaces used for the processing of semiconductor substrates.

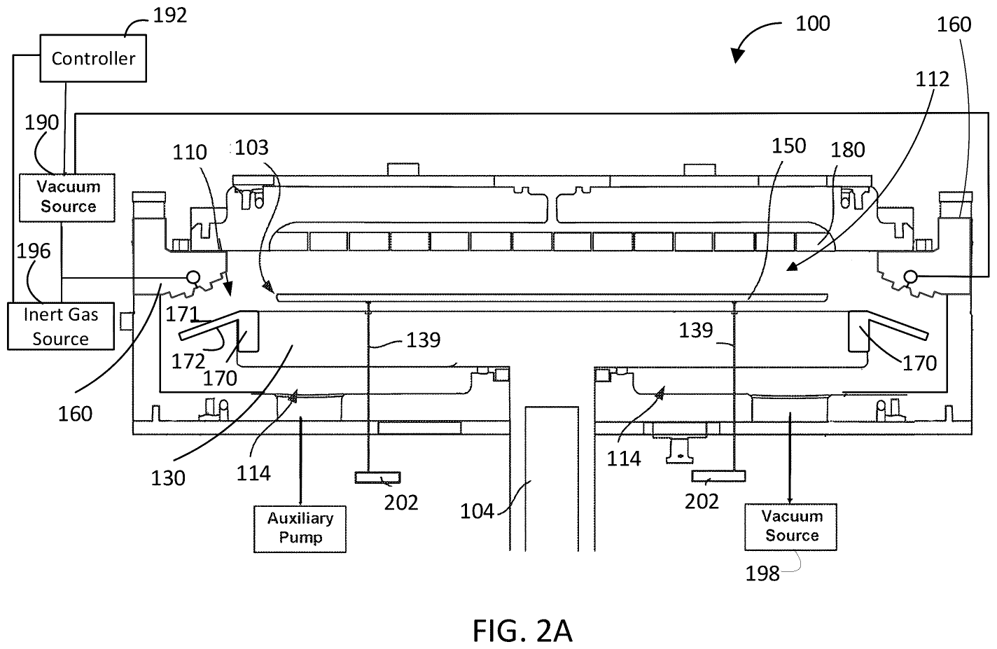

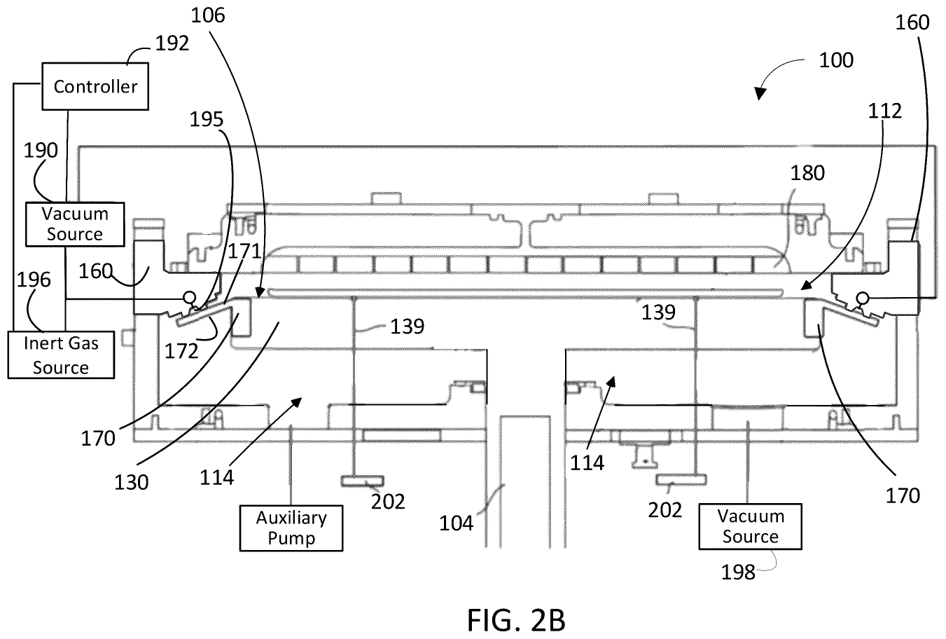

Turning to FIGS. 2A and 2B, the embodiments of the disclosure may include reactor systems and methods that may be utilized for processing a substrate within a reactor 100. In various embodiments, a reactor 100 may comprise a reaction chamber 110 for processing substrates. In various embodiments, the reaction chamber 110 may comprise an upper chamber space 112, which may be configured for processing one or more substrates, and/or a lower chamber space 114. The lower chamber space 114 may be configured for the loading and unloading of substrates from the reaction chamber, and/or for providing a pressure differential between lower chamber space 114 and the upper chamber space 112.

In various embodiments, a substrate 150 and a susceptor 130 may be movable relative to one another. For example, in various embodiments, lift pins 139 may be configured to allow substrate 150 to separate from susceptor 130 and/or to allow substrate 150 to be placed in contact with (i.e., to be supported by) susceptor 130. In various embodiments, the susceptor 130 may move, for example, via a susceptor elevator 104, up or down such that the substrate 150 moves with the susceptor 130. In various embodiments, the lift pins 139 may move up or down, for example, via lift pin elevators/platforms 202. In various embodiments, one of the susceptor 130 and the lift pins 139 may be stationary while the other is moving.

In various embodiments, the susceptor 130 may move from the loading position 103 to the processing position 106 as illustrated in FIG. 2B, thus moving the substrate 150 into the upper chamber space 112. The substrate 150 may be subsequently processed within the upper chamber space 112. Fluids (e.g., precursors, reactant gases, carrier gases, and the like) may flow into the upper chamber space 112 through a fluid distribution system 180 (e.g., a showerhead) to contact the substrate 150. A volume of the upper chamber space 112 within the reaction chamber 110 may be enclosed at least by the fluid distribution system 180, the susceptor 130, a spacer plate 160, and/or a sealing member 170.

The sealing member 170 may be set around the susceptor 130. The sealing member 170 may be ring-shaped and/or attached to the susceptor 130. The sealing member 170 may have an inner periphery that has a diameter greater than a diameter of the substrate-supporting area on the susceptor 130. The susceptor 130 may have an annular lip portion on its top surface outside the substrate-supporting area, and the sealing member 170 may be disposed on the top surface outside the lip portion. Alternatively, the susceptor 130 may have no annular lip portion on a top surface outside the substrate-supporting area, and the sealing member 170 may be disposed on the top surface outside the substrate-supporting area.

The susceptor 130 may comprise a top plate (not shown) and a heating block (not shown) on which the top plate is placed. The sealing member 170 may be ring-shaped and interposed between the top plate and the heating block. The sealing member 170 may be attached to a side of the heating block. The sealing member 170 may have a ring portion and an annular peripheral portion that extends from the susceptor 130. The ring portion may be attached to a side of the heating block. The annular peripheral portion may comprise an upward facing surface 171 and a downward facing surface 172.

The sealing member 170 may move with the susceptor when the susceptor 130 is raised or lowered inside the reaction chamber. When the susceptor 130 is raised to the processing position 106, the upward facing surface of the sealing member 170 may be in contact with the spacer plate 160.

The sealing member 170 may be formed of an elastic material, such as a heat-resistant elastic material, such as silicone; perfluoroelastomer (for example, perfluorinated rubber (FFKM)), such as Kalrez® brand products; or fluoropolymer (for example, fluororubber), such as, for example, a Viton™ brand product. For example, a maximum operating temperature of Viton™ brand products may be 230° C., while the maximum operating temperature for Kalrez® brand products may be 330° C. In various embodiments, the reactor 100 may be configured to process the substrate below 200° C., and therefore, the sealing member 170 may comprise either Viton™ brand products or Kalrez® brand products. In other embodiments, the reactor 100 may be configured to process the substrate below 300° C., and therefore, the sealing member 170 may comprise Kalrez® brand products.

In various embodiments, the reactor 100 may comprise a spacer plate 160, at least a portion of which may be protruding from the chamber side wall into the reaction chamber. The spacer plate 160 may be disposed below the fluid distribution system 180. In various embodiments, the spacer plate 160 may surround the susceptor in the reaction chamber 110. The spacer plate 160 may be coupled with the sealing member 170 when the susceptor 130 moves into or is disposed in a processing position (e.g., a raised position). For example, a downward-facing surface of the spacer plate 160 may be coupled with and/or in contact with an upward-facing surface of the sealing member 170.

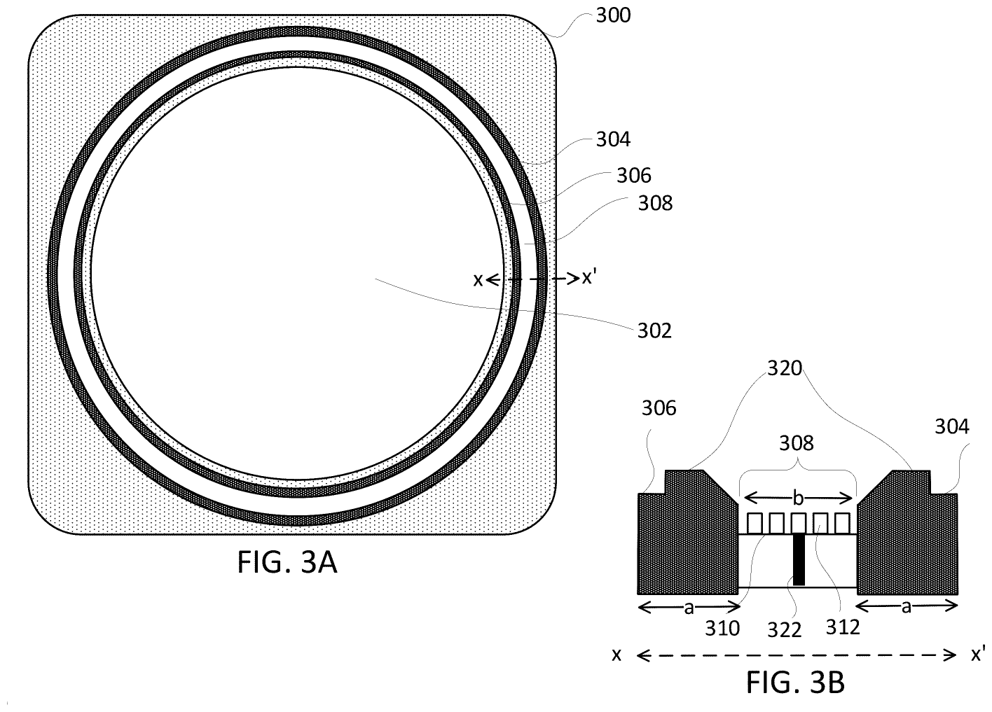

FIG. 3A illustrates a top view of a downward-facing surface of an example spacer plate 300 (e.g., the spacer plate 160), while FIG. 3B illustrates a cross-section view of the spacer plate 300. The spacer plate 300 may comprise an opening 302 that enables fluids from the fluid distribution system 180 to enter the upper chamber space 112. The spacer plate 300 may further comprise an outer raised portion 304, an inner raised portion 306, and/or a depressed portion 308. In various embodiments, the outer raised portion 304 may have a first circumference C1, the depressed portion 308 may have a second circumference C2, and the inner raised portion 306 may have a third circumference C3. The second circumference C2 may be less than the first circumference C1 and greater than the third circumference C3. The first circumference C1 may be greater than the second and third circumferences C2, C3. The height of the outer raised portion 304 and/or the inner raised portion 306 may be greater than the height of the depressed portion 308. The width “a” of the outer raised portion 304 and/or the inner raised portion 306 may be in the range of 10 to 30 nanometers. The outer raised portion 304 and/or the inner raised portion may comprise smooth surfaces 320 that may be in contact with the sealing member 170. Additionally, the width “b” of the depressed portion may be in the range of 10-20 nanometers. The spacer plate 300 may comprise a material such as quartz, ceramic, or a metal, such as titanium, aluminum, stainless steel, or Hastelloy.

In various embodiments, a surface 310 of the depressed portion 308 may comprise one or more bits 312. The bits 312 may have a cylindrical shape, a cuboid shape, a hexagonal prism shape, a triangular prism shape, and the like. The width of the bits 312 may be 1-2 nm, while the height of the bits may be 2-10 nm. The bits 312 may be configured to prevent the upward facing surface 171 of the sealing member 170 from contacting the downward facing surface 172 of the depressed portion 308. Additionally, the bits 312 may be configured to create a uniform vacuum between the upward facing surface 171 of the sealing member 170 and the spacer plate 300. The depressed portion 308 may further comprise an inlet 322 that is coupled to a vacuum source (e.g., the vacuum source 190) and/or an inert gas source (e.g., the inert gas source 196).

Referring back to FIGS. 2A and 2B, in various embodiments, the spacer plate 160 and the sealing member 170 may be configured to control fluid flow within a reaction chamber. The upper chamber space 112 and the lower chamber space 114 may be separated or isolated (fluidly and/or physically) by the sealing member 170 and/or the spacer plate 160. For example, the sealing member 170 attached to the susceptor 130 may be coupled to, in contact with, and/or engaged with the raised portions of the spacer plate 160 (e.g., the outer raised portion 304 and the inner raised portion 306) when the susceptor 130 is at the processing position 106. In various configurations, the pressure within the lower chamber space 114 may be increased such that the increased pressure pushes the sealing member 170 upward such that the upward facing surface 171 of the sealing member 170 is in contact with the raised portions of the spacer plate 160. The lower chamber space 114 may be coupled to a vacuum source 198 (e.g., a vacuum pump). The vacuum source 198, when activated, may provide vacuum pressure, causing gas to flow from the vacuum source 198 to the lower chamber space 114, thereby increasing the internal pressure within the lower chamber space 114. The vacuum source 198, when deactivated, may cause gas to flow from the lower chamber space 114 to the vacuum source 198.

The sealing member 170 and/or the spacer plate 160 may fluidly separate the upper chamber space 112 and the lower chamber space 114 by creating at least a partial vacuum seal between a portion of the sealing member 170 and a portion of the spacer plate 160. For example, the partial vacuum seal may be formed in a space 195 enclosed by the sidewalls of the raised portions of the spacer plate 160, the depressed portion (e.g., the depressed portion 308) of the spacer plate, and a portion of the sealing member 170 between the raised portions of the spacer plate 160. The portion of the sealing member 170 between the raised portions of the spacer plate 160 may deform and extend toward the depressed portion of the spacer plate 160. The spacer plate 160 may be coupled (e.g., via the inlet 322) to a vacuum source 190 (e.g., a vacuum pump) and/or to an inert gas source 196. The vacuum source 190, when activated, may provide vacuum pressure, causing gas to flow from the space 195 to the vacuum source 190, thereby forming a vacuum seal in the space 195. The vacuum source 190, when deactivated, may cause gas to flow from the space 195 to the vacuum source 190, thereby releasing the vacuum seal formed in the space 195. Furthermore, after the vacuum source 190 is deactivated, the inert gas source 196 may be activated to enable one or more inert gases (e.g., N2, Ar, He, etc.) to flow from the inert gas source 196 to the space 195 to release the vacuum seal formed in the space 195. The inlet 322 of the depressed region 308 of the spacer plate may provide a passage for the gas flow between the space 195 and the vacuum source 196. A controller 192 may control the formations and/or releases of vacuum seals within the space 195 by controlling the activating and/or deactivating of the vacuum source 190 and the activating and/or deactivating of the inert gas source 196.

The at least partial vacuum sealing of the upper chamber space 112 from the lower chamber space 114 may be desirable to prevent or reduce precursor gases, and/or other fluids, utilized in the processing of a substrate 150, from entering and/or contacting the lower chamber space 114 of reaction chamber 110. For example, the precursor gases utilized for processing substrates in the reaction space may comprise corrosive deposition precursors, which may contact the lower chamber space 114, producing unwanted deposits/contaminants/particles, which may, in turn, be reintroduced into the upper chamber space 112 later on, thereby providing a source of contamination to a substrate disposed in the reaction space. The at least partial vacuum sealing of the upper chamber space 112 from the lower chamber space 114 may also limit the area in which plasma is generated. Various other embodiments, embodiments described herein may also prevent plasma from coming in contact with the side faces of the susceptor (e.g., a heating block), interior walls of the reactor 100 and other locations where conductive members are exposed, which consequently results in a lower floating potential applied to the processing target. As a result, occurrences of charging damage caused by plasma and pickup problems may be reduced.

In various embodiments, to create a vacuum seal between the upper chamber space 112 and the lower chamber space 114, a reaction chamber 110 may comprise a sealing system disposed between the susceptor 130, the chamber sidewalls of the reaction chamber, and/or the fluid distribution system 180. For example, the sealing system in reaction chamber 110 may comprise a sealing member 170 attached to the susceptor 130, a spacer plate 160, a vacuum source 190 to create at least a partial vacuum seal between the upper chamber space 112 and the lower chamber space 114, an inert gas source 196 to release the partial vacuum seal, and/or a controller 192.

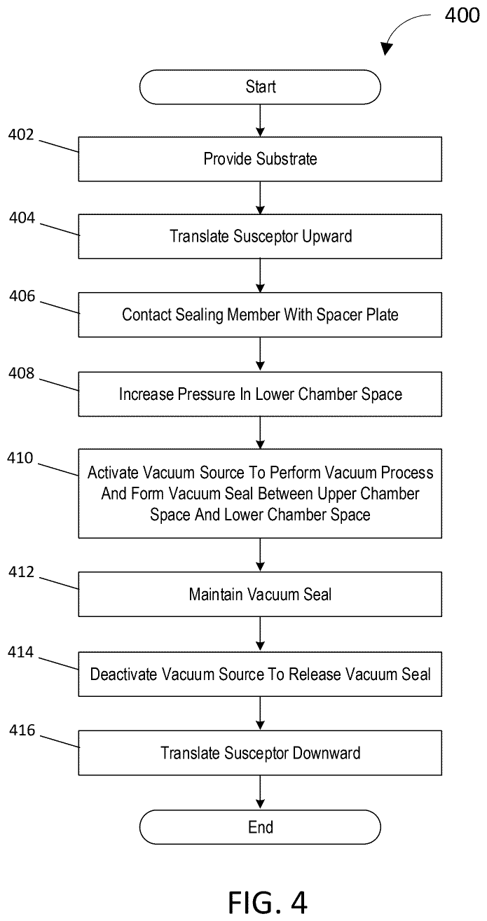

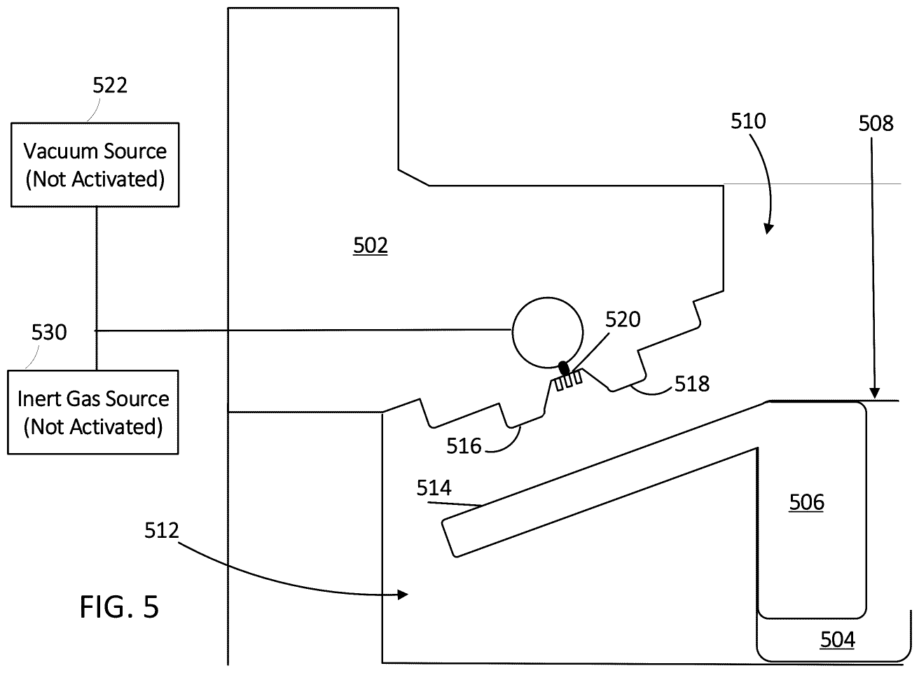

In operation, with reference to method 400 shown in FIG. 4, at step 402, a substrate (e.g., substrate 150) may be provided in a reaction chamber (e.g., the reaction chamber 110 of the reactor 100). At the time when the substrate is provided, the susceptor supporting the substrate may be at a first position (e.g., a lower position or loading position). For example, FIG. 5 illustrates a susceptor 504 (e.g., the susceptor 130) where the upward facing surface of the susceptor 504 may be at the first position 508 (e.g., a lower position or loading position). A sealing member 506 (e.g., the sealing member 170) may be attached to the susceptor 504, and when the susceptor 504 is at first position 508, the upward facing surface 514 of the sealing member 506 is not in contact with the raised portions 516 and 518 of the spacer plate 502 (e.g., the outer raised portion 304 and the inner raised portion 306). The spacer plate 502 may also comprise a depressed portion 520 (e.g., the depressed portion 308) between the raised portions 516 and 518, and the depressed portion 520 may be coupled to a vacuum source 522 (e.g., the vacuum source 190) and/or an inert gas source 530. When the upward facing surface of the susceptor 504 is at the first position 508, fluid may flow freely between the upper chamber space 510 (e.g., the upper chamber space 112) and the lower chamber space 512 (e.g., the lower chamber space 114). Accordingly, the sealing member 506 may be in a relaxed condition (e.g., no deformation or expansion).

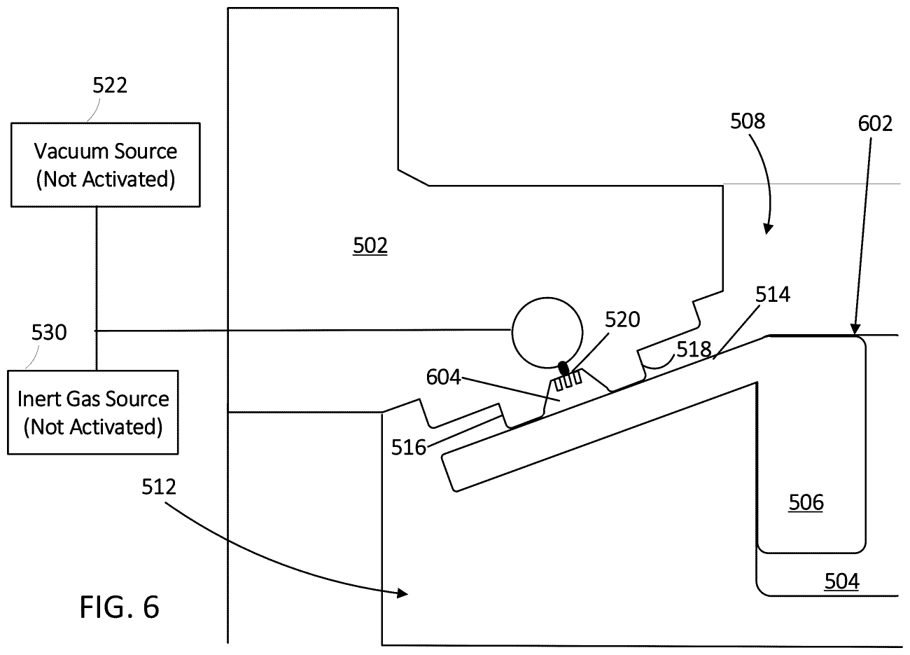

Referring back to FIG. 4, at step 404, the susceptor may translate upward from a first position (e.g., a lower position or loading position) to a second position (e.g., a raised position or processing position) such that at step 406, a sealing member attached to the susceptor may contact portions of a spacer plate. For example, as shown in FIG. 6, the susceptor 504 may be translated upward such that the upward facing surface of the susceptor 504 is at a raised or processing position 602. The processing position of a susceptor 504 may be the position at which the susceptor 504 is disposed (e.g., at a desired distance from the top or fluid distribution system of the reaction chamber) during the processing of the substrate. During translation, an upward facing surface 514 of the sealing member 506 may engage with, make contact with, and/or couple to the raised portions 516 and 518 of the spacer plate 502. The contact between the upward facing surface 514 of the sealing member 506 and the raised portions 516 and 518 of the spacer plate 502 may create a space 604. The space 604 may be enclosed or surrounded by the sidewalls of the raised portions 516 and 518, the upward facing surface 514 of the sealing member 506, and/or the downward facing surface of the depressed portion 520. The vacuum source 522 may not be activated, and therefore, the sealing member 506 may still be in a relaxed position (e.g., no deformation or expansion).

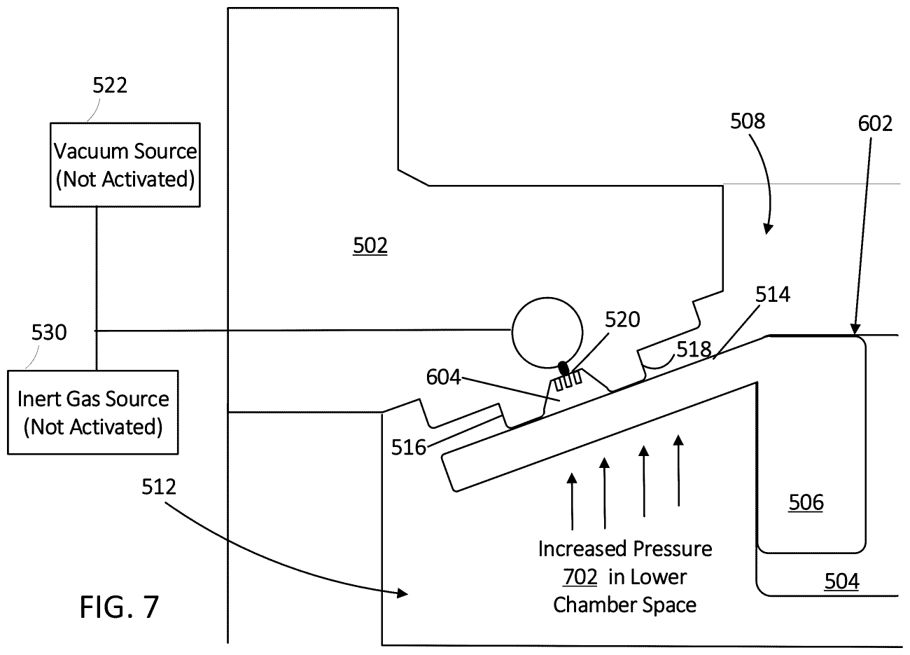

At step 408 of FIG. 4, pressure within a lower chamber space of the reactor chamber may be increased. For example, as illustrated in FIG. 7, increased pressure 702 may push the annular peripheral portion of the sealing member 506 upward such that the upward facing surface 514 of the sealing member 506 may be in contact with the raised portions 516 and 518 of the spacer plate 502. The lower chamber space 512 may be coupled to a vacuum source (e.g., the vacuum source 198), which, when activated, may provide vacuum pressure, causing gas to flow from the vacuum source to the lower chamber space 512, thereby increasing the internal pressure within the lower chamber space 512.

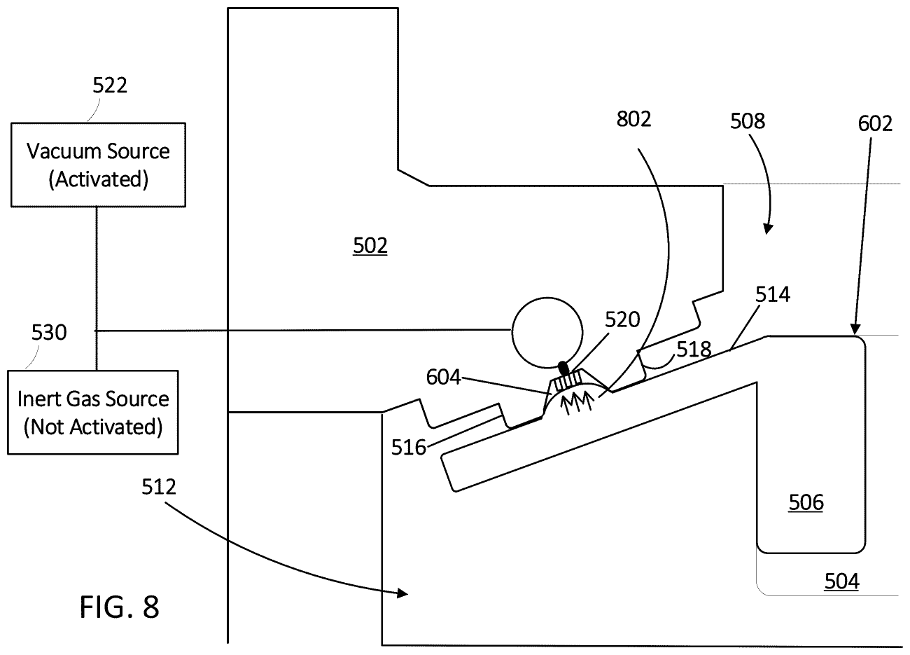

At step 410 of FIG. 4, a vacuum seal may be formed between an upper chamber space and a lower chamber space of the reaction chamber by activating a vacuum source coupled to the reaction chamber. For example, as illustrated in FIG. 8, the vacuum source 522 may be activated, and a vacuum process may be performed in the space 604. The vacuum process may comprise causing gas to flow from the space 604 to the vacuum source 522, thereby forming a vacuum seal in the space 604. The sealing member 506 may comprise an elastic material, and forming a vacuum within the space 604 may cause the elastic material of a portion 802 of the sealing member 170 to deform and extend toward the depressed portion 520 of the spacer plate 502. The extended portion 802 may be in contact with one or two bits disposed on the downward facing surface of the depressed portion 520. The bits may present the extended portion 802 from being in direct contact with the downward facing surface of the depressed portion 520. The vacuum source 522 may be activated when the vacuum source 522 receives an activation signal from a controller (e.g., the controller 192).

In response to the vacuum seal formed in the space 604, at least a partial vacuum seal may be formed between the spacer plate 502 and the sealing member 506, and the upper chamber space 510 may be isolated from the lower chamber space 512. Accordingly, the upper chamber space 510 may be at least partially fluidly isolated from the lower chamber space 512.

At step 412 of FIG. 4, the vacuum seal (e.g., the vacuum seal formed in the space 604) may be maintained while a substrate of step 402 is processed within the upper chamber space 510. The vacuum seal may be maintained by keeping the vacuum source turned on.

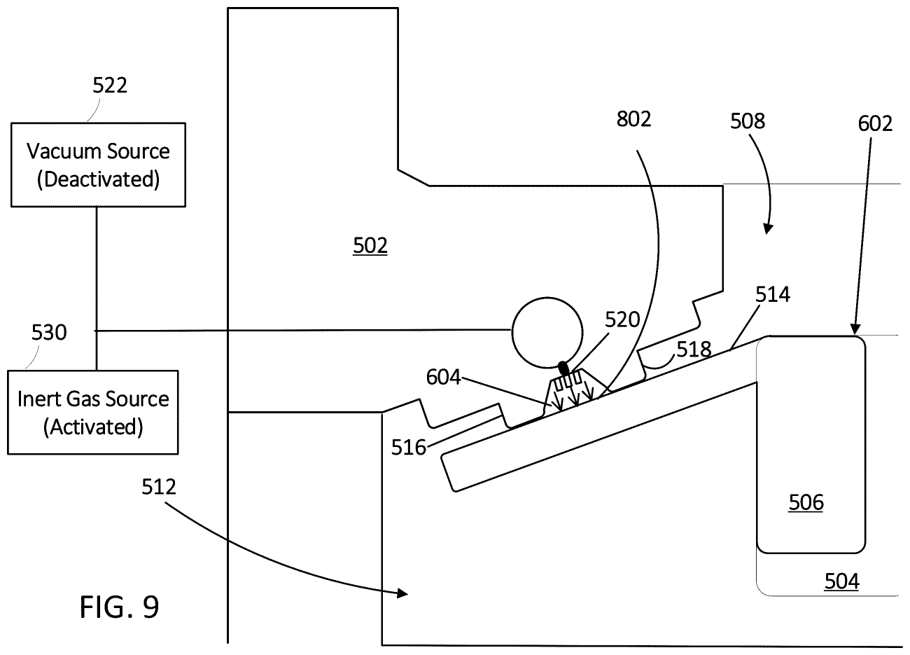

At step 414 of FIG. 4, the vacuum source may be deactivated to release the vacuum seal. In addition, an inert gas source may be activated. For example, as illustrated in FIG. 9, the vacuum source 522 may be deactivated, and the inert gas source 530 may be activated. The inert gas source 530 may cause gas to flow from the inert gas source 530 to the space 604, thereby releasing the vacuum seal in the space 604. For example, one or more inert gasses (e.g., molecular nitrogen, helium, argon, or other inert gas) may be pumped into the space 604. The elastic material of the extended portion 802 may revert to its relaxed condition. Gas recently pumped inside the space 604 may aid the extended portion 802 to revert to its relaxed condition. The vacuum source 522 may be deactivated when receiving a deactivation signal from a controller (e.g., the controller 192).

At step 416 of FIG. 4, the susceptor 504 may translate downward from the raised position (e.g., the raised position 602) to a lower position (e.g., the first position 508 or another lower position). Translating the susceptor downward may allow fluid to flow freely again between the upper chamber space 510 and the lower chamber space 512.

Although exemplary embodiments of the present disclosure are set forth herein, it should be appreciated that the disclosure is not so limited. For example, although reactor systems are described in connection with various specific configurations, the disclosure is not necessarily limited to these examples. Various modifications, variations, and enhancements of the system and method set forth herein may be made without departing from the spirit and scope of the present disclosure.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A reaction chamber, comprising:
a susceptor configured to:
support a substrate disposed in the reaction chamber; and
translate upwardly and downwardly within the reaction chamber;
an upper chamber space within the reaction chamber and above the susceptor;
a lower chamber space within the reaction chamber and below the susceptor; and
a sealing system comprising:
a sealing member attached to the susceptor; and
a spacer plate surrounding the susceptor,
wherein the sealing system is configured to form at least a partial vacuum seal between the spacer plate and the sealing member and cause at least partial fluid separation between the upper chamber space and the lower chamber space.

2. The reaction chamber of claim 1, wherein the sealing system is configured to form the partial vacuum seal between the spacer plate and the sealing member by forming the partial vacuum seal between an upward facing surface of the sealing member and a downward facing surface of the spacer plate.

3. The reaction chamber of claim 1, wherein the sealing member comprises an elastic material; and
wherein the sealing member is configured to expand when the partial vacuum seal is formed between the spacer plate and the sealing member.

4. The reaction chamber of claim 1, wherein the spacer plate comprises:
a first raised portion;
a second raised portion; and
a depressed portion between the first raised portion and the second raised portion,
wherein the sealing system is configured to form the partial vacuum seal between the spacer plate and the sealing member by performing a vacuum process in a space formed by sidewalls of the first raised portion and the second raised portion, the depressed portion, and an upward facing surface of the sealing member.

5. The reaction chamber of claim 4, wherein one of the first raised portion or the second raised portion comprises a width of 5 to 30 millimeters.

6. The reaction chamber of claim 4, wherein the depressed portion has a width of 5 to 30 millimeters.

7. The reaction chamber of claim 4, wherein the sealing system further comprises:
one or more bits disposed on the depressed portion and configured to prevent the upward facing surface of the sealing member from contacting a surface of the depressed portion.

8. The reaction chamber of claim 1, wherein the reaction chamber is configured to process the substrate at a temperature of less than 200° C.

9. The reaction chamber of claim 1, wherein the sealing system further comprises a vacuum source coupled to the spacer plate; and
wherein the sealing system is configured to form the partial vacuum seal between the spacer plate and the sealing member by:
causing the susceptor to translate upwardly within the reaction chamber;
causing an upward facing surface of the sealing member to contact a downward facing surface of the spacer plate; and
activating the vacuum source to form the partial vacuum seal between the spacer plate and the sealing member.

10. The reaction chamber of claim 9, wherein the sealing system is further configured to form the partial vacuum seal between the spacer plate and the sealing member by:
increasing pressure in the lower chamber space.

11. The reaction chamber of claim 9, wherein the sealing system is further configured to release the partial vacuum seal between the spacer plate and the sealing member by:
deactivating the vacuum source; and
causing the susceptor to translate downwardly within the reaction chamber.

12. The reaction chamber of claim 1, wherein the spacer plate comprises a metal or a metal alloy.

13. A sealing system, comprising:
a sealing member attached to a susceptor in a reaction chamber;
a spacer plate surrounding the susceptor;
a vacuum source coupled to the spacer plate; and
a controller configured to turn on the vacuum source to cause formation of at least a partial vacuum seal between the spacer plate and the sealing member and cause at least partial fluid separation between an upper chamber space of the reaction chamber and a lower chamber space of the reaction chamber, wherein the upper chamber space is above the susceptor and the lower chamber space is below the susceptor.

14. The sealing system of claim 13, wherein the sealing member comprises an elastic material and is configured to expand when the partial vacuum seal is formed between the spacer plate and the sealing member.

15. The sealing system of claim 13, wherein the spacer plate comprises:
a first raised portion;
a second raised portion; and
a depressed portion between the first raised portion and the second raised portion,
wherein the controller is configured to cause formation of the partial vacuum seal between the spacer plate and the sealing member by causing the vacuum source to perform a vacuum process in a space formed by sidewalls of the first raised portion and the second raised portion, the depressed portion, and an upward facing surface of the sealing member.

16. The sealing system of claim 15, further comprising:
one or more bits disposed on a first surface of the depressed portion and configured to prevent the upward facing surface of the sealing member from contacting the first surface of the depressed portion.

17. The sealing system of claim 13, wherein the controller is further to turn off the vacuum source to cause a release of the partial vacuum seal between the spacer plate and the sealing member r.

18. A method, comprising:
translating a susceptor in a reaction chamber upwardly from a first position to a second position;
contacting, based on the translating, an upward facing surface of a sealing member with a downward facing surface of a spacer plate in the reaction chamber, wherein the sealing member is coupled to the susceptor, and wherein the spacer plate surrounding the susceptor;
activating a vacuum source, coupled to the spacer plate, to form at least a partial vacuum seal between the downward facing surface of the spacer plate and the upward facing surface of the sealing member and to cause at least partial fluid separation between an upper chamber space of the reaction chamber and a lower chamber space in the reaction chamber, wherein the upper chamber space is above the susceptor and the lower chamber space is below the susceptor; and
maintaining, during processing of a substrate within the upper chamber space, the partial vacuum seal between the spacer plate and the sealing member.

19. The method of claim 18, further comprising:
increasing pressure in the lower chamber space.

20. The method of claim 18, further comprising:
after the processing of the substrate:
deactivating the vacuum source to release the partial vacuum seal; and
translating the susceptor downwardly from the second position to a third position.
